(19) United States
(12) Patent Application Publication
(10) Pub. No.: US 2022/0359219 A1
(43) Pub. Date: Nov. 10, 2022

(54) Chemical Mechanical Polishing With Die-Based Modification

(71) Applicant: Applied Materials, Inc., Santa Clara, CA (US)

(72) Inventors: Haosheng Wu, San Jose, CA (US); Shou-Sung Chang, Mountain View, CA (US); Jianshe Tang, San Jose, CA (US); Brian J. Brown, Palo Alto, CA (US); Alexander John Fisher, Santa Clara, CA (US); Hari Soundararajan, Sunnyvale, CA (US); Mayu Felicia Yamamura, San Carlos, CA (US)

(21) Appl. No.: 17/735,021

(22) Filed: May 2, 2022

Related U.S. Application Data
(60) Provisional application No. 63/184,132, filed on May 4, 2021.

(51) Int. Cl. H01L 21/306

(52) U.S. Cl. CPC H01L 21/30625

(57) ABSTRACT

A method of processing a substrate includes selectively dispensing a treatment fluid on a die-by-die basis to onto a substrate, and chemical mechanical polishing the substrate after dispensing the treatment fluid. The treatment fluid modifies a polishing rate of the chemical mechanical polishing at one or more selected die(s) to which the treatment fluid is applied in comparison to one or more remaining die(s) to which the treatment fluid is not applied.

### CROSS-REFERENCE TO RELATED APPLICATION

This application claims priority to U.S. Provisional Application Ser. No. 63/184,132, filed on May 4, 2021, the disclosure of which is incorporated by reference.

### TECHNICAL FIELD

The present disclosure relates to chemical mechanical polishing and more specifically to die-to-die modification of polishing.

### BACKGROUND

An integrated circuit is typically formed on a substrate by the sequential deposition of conductive, semiconductive, or insulative layers on a silicon wafer. A variety of fabrication processes require planarization of a layer on the substrate. For example, one fabrication step involves depositing a filler layer over a non-planar surface of an underlying layer and planarizing the filler layer. For some applications, the filler layer is planarized until the top surface of the underlying layer is exposed. For other applications, the filler layer is planarized until a specific thickness remains over the underlying layer.

Chemical mechanical polishing (CMP) is one accepted method of planarization. This planarization method typically requires that the substrate be mounted on a carrier head. The exposed surface of the substrate is typically placed against a rotating polishing pad. The carrier head provides a controllable load on the substrate to push it against the polishing pad. A polishing liquid, e.g., a slurry with abrasive particles, is typically supplied to the surface of the polishing pad.

One problem in CMP is that variations in the slurry distribution, the polishing pad condition, the relative speed between the polishing pad and the substrate, the initial thickness of the substrate layer, and the load on the substrate can cause variations in the material removal rate across substrate.

### SUMMARY

In one aspect, a method of processing a substrate includes selectively dispensing a treatment fluid on a die-by-die basis to onto a substrate, and chemical mechanical polishing the substrate after dispensing the treatment fluid. The treatment fluid modifies a polishing rate of the chemical mechanical polishing at one or more selected die(s) to which the treatment fluid is applied in comparison to one or more remaining die(s) to which the treatment fluid is not applied.

In another aspect, a system includes a treatment station including a dispenser to deliver a treatment fluid on a die-by-die basis to onto a substrate, a chemical mechanical polishing station, and a substrate transfer robot to transfer the substrate from the treatment station to the chemical mechanical polishing station. The treatment fluid is a material that modifies a polishing rate at one or more selected die(s) to which the treatment fluid is applied in comparison to one or more remaining die(s) to which the treatment fluid is not applied in a subsequent chemical mechanical polishing/Implementations may provide, but are not limited to, one or more of the following advantages.

The amount of material removed can be varied on a die-to-die basis, thereby improving polishing uniformity.

The details of one or more implementations are set forth in the accompanying drawings and the description below. Other features, objects, and advantages will be apparent from the description and drawings, and from the claims.

### DESCRIPTION OF DRAWINGS

FIG. 1 is a schematic cross-sectional view of an example chemical mechanical polishing system.

FIG. 2 illustrates a schematic top view of a substrate having multiple zones.

FIG. 3 is a flow diagram of an example process for modifying a polishing operation on a die-by-die basis.

Like reference symbols in the various drawings indicate like elements.

### DETAILED DESCRIPTION

When a substrate that includes multiple dies is polished using a chemical mechanical polishing process, sometimes the substrate material is removed at different rates at different locations of the surface. If the polishing process terminates when some dies are adequately polished, other dies may have be over-polished or be under-polished and be non-usable.

One approach to compensating for non-uniform polishing is to use a carrier head with multiple independently controllable concentric pressurizable chambers. This can compensate for radial non-uniformity, but not for angular (i.e., circumferential) non-uniformity, aka asymmetric polishing. Carrier heads with angularly distributed chambers have been proposed, but such carrier heads might not provide the necessary resolution to address die-to-die variations in polishing rate.

However, a technique to improve polishing uniformity on a die-to-die basis is to perform one or more preliminary treatment steps. The treatment step is performed before the polishing step on a die-to-die basis and modifies effectiveness of the subsequent polishing operation. For example, the treatment step can provide a protective coating to reduce the polishing rate on a die, or modify the surface of the die (without necessarily removing material) in order to increase the polishing rate on a die.

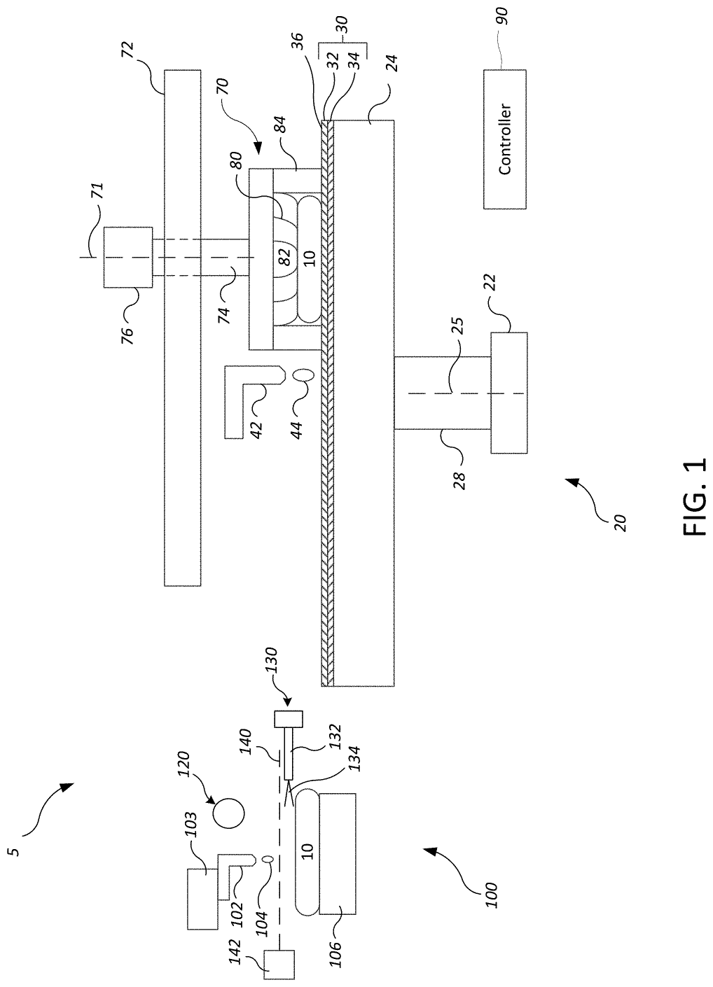

FIG. 1 illustrates an example of chemical mechanical polishing system 5 that includes both a polishing station 20 and a preliminary treatment station 100. In some implementations, the chemical mechanical polishing system 5 includes an in-line metrology system to measure layer thickness at one or more dies on the substrate 10.

The polishing station 20 includes a rotatable disk-shaped platen 24 on which a polishing pad 30 is situated. The platen 24 is operable to rotate about an axis 25. For example, a motor 22 can turn a drive shaft 28 to rotate the platen 24. The polishing pad 30 can be a two-layer polishing pad with an outer polishing layer 34 and a softer backing layer 32.

The polishing station 20 can include a supply port 42, e.g., at the end of a slurry supply arm, to dispense a polishing liquid 44, such as an abrasive slurry, onto the polishing pad 30. The polishing station 20 can also include a conditioner system with a conditioning disk to abrade the polishing pad to keep the polishing pad with a consistent roughness from substrate-to-substrate.

A carrier head 70 is operable to hold a substrate 10 against the polishing pad 30. The carrier head 70 is suspended from a support structure 72, e.g., a carousel or a track, and is connected by a drive shaft 74 to a carrier head rotation motor 76 so that the carrier head can rotate about an axis 71. Optionally, the carrier head 70 can oscillate laterally, e.g., on sliders on the carousel, by movement along the track, or by rotational oscillation of the carousel itself.

The carrier head 70 can include a flexible membrane 80 having a substrate mounting surface to contact the back side of the substrate 10, and a plurality of pressurizable chambers 82 to apply different pressures to different zones, e.g., different radial zones, on the substrate 10. The carrier head 70 can include a retaining ring 84 to hold the substrate. In operation, the platen is rotated about its central axis 25, and the carrier head is rotated about its central axis 71 and translated laterally across the top surface of the polishing pad 30.

In some implementations, the polishing apparatus includes an in-situ monitoring system, e.g., an optical monitoring system or an eddy current monitoring system, which can be used to monitor the thickness of a layer being polishing on the substrate.

The treatment station 100 includes a dispenser 102 to selectively deliver a treatment fluid 104 onto selected dies on the substrate. In some implementations, the treatment station 100 includes a support 106. The substrate support 106 can be a CMP carrier head, a chuck stage where the substrate is facing up or down, or a fixture with lift pins or contact pins to hold the substrate. The substrate can be held face up, face down, or at another angle, e.g., vertically.

The dispenser can include a nozzle or multiple nozzles to deliver the treatment fluid to the selected die(s). The nozzles can move in x-y directions or follow designated motion paths. The nozzles can have an adjustable height and spreading angle to ensure the coverage of the selected die(s) while minimizing the overflow of chemicals of other dies. The chemicals of the treatment fluid can also be delivered by a foam, or other materials saturated with the chemicals and placed in contact with the selected dies.

In some implementations, an actuator 103 is connected to the dispenser 102 or the support 106 to control their relative position. The actuator 103 can include a pair of linear actuators to move the dispenser 102 or the support 106 in two perpendicular directions. Possible dispenser mechanisms include droplet ejection (e.g., by piezoelectric actuation), spin-on, spray-on, and screen printing.

The chemistry of the fluid will depend on the type of treatment, as discussed further below. In some implementations, depending on the dispensing mechanism, the treatment station 100 includes a mask 140 to control the regions of the surface of the substrate to which the treatment fluid 104 is applied. The mask 140 can be used when the specific dies that need treatment are the same from substrate-to-substrate, e.g., to correct for consistent non-uniformity from an upstream process. The mask 140 can be held at a fixed height relative to the substrate surface during the dispensing process, allowing only specific areas on the substrate to receive treatment. In some implementations, a vertical actuator 142 can adjust the distance between the top surface of the substrate 10 and the mask 140.

For screen printing, the mask 140 can be held in contact with the substrate surface, and the dispenser can include a roller or blade to spread the treatment fluid across the substrate 10. For droplet ejection, the dispenser 102 can be moved by the actuator 103 laterally across the substrate while ejection is controlled such that the treatment fluid is dispensed only on the selected die(s), but the mask 140 can be used to prevent ejection onto other areas on the substrate 10. For spin-on printing, the treatment fluid can flow from the dispenser while the support 106 rotates.

Depending on the treatment technique, the treatment station 100 can also include an energy source 120 to cure the treatment fluid. For example, the energy source can be UV light source, or an array of UV light source, to cure the fluid, e.g., cross-link polymers. Alternatively, the energy source can be a heater, e.g., an IR lamp or an array of IR lamps, that provide thermal treatment after applying the fluid. In some implementations, the energy source is scanned across the substrate, e.g., by an actuator, and controllably modulated to treat the specific regions corresponding to the selected die(s).

Depending on the treatment technique, the treatment station 100 can also include a substrate surface cleaner 130. The surface cleaner 130 can include a fluid source and an outlet 132 positioned to flow the fluid 134 across the surface of the substrate 10. In some implementations, the fluid is a gas, e.g., filtered air, N2, or an inert gas. The gas can be used to blow excess water and/or polishing fluid off of the selected die(s) before applying the surface treatment fluid, e.g., if the surface treatment happens in between two CMP steps. In some implementations, the fluid is a liquid, e.g., DI water, to remove the treatment fluid, e.g., to remove etchant. In some implementations, e.g., if the treatment fluid is a photoresist, the fluid is a developer to remove exposed or unexposed portions of the treatment fluid. The substrate surface cleaner 130 can also include a vacuum source to suction away excess treatment fluid. Thus, the substrate surface cleaner can include a chemical or gas delivery nozzle, array of chemical or gas delivery nozzles, a vacuum nozzle, or array of vacuum nozzles.

The polishing station 20 and the treatment stations 100 can be integrated into a single tool. In this case, in operation, a substrate 10 to be polished can be transferred, e.g., from a cassette through a factory interface module, to the treatment station 100 before the substrate 10 is polished at the polishing station 20. The substrate is then transferred to the polishing station 20, polished, and then returned through the factory interface module to the same or a different cassette. In some implementations, the substrate 10 is transferred from the treatment station 100 to the polishing station 20 while remaining in the same carrier head 70, e.g., by movement of the carrier head along a track or by rotation of a carousel. In such implementations, the substrate would remain in either a face-up or face-down position for both treatment and polishing. In some implementations, the substrate 10 is transferred from the treatment station 100 to the polishing station 20 by a separate robot. For example, the substrate can be treated at an in-line treatment station, then picked by a robot and inserted into a loading station of the polishing system. In such implementations, the substrate can be flipped by the robot from a face-up to a face-down orientation when being transferred, or the substrate can remain in either a face-up or face-down position for both treatment and polishing.

In some implementations, the polishing station 20 and the treatment station 100 are stand-alone with respect to each other and are located in the vicinity of each other, e.g., in the same clean room.

The polishing apparatus 5 can be controlled by a control system 90, e.g., a controller such as a programmed computer or micro-controller. For example, the control system can control various parameters of the polishing station 20, e.g., motors or actuators to control the carrier head position and rotation rate, platen rotation rate, polishing liquid flow rate, etc. Similarly, the control system 90 can control various parameters of the treatment station 100, e.g., the actuator 103 to control the relative position of the substrate 10 and dispenser 102, valves to control timing of dispensing of the treatment fluid 104 so as to controllably dispense the treatment fluid at selected locations. Moreover, the control system 90 can control the motion of the robot or other transfer mechanism that transports the substrate from the treatment station 100 to the polishing station 20.

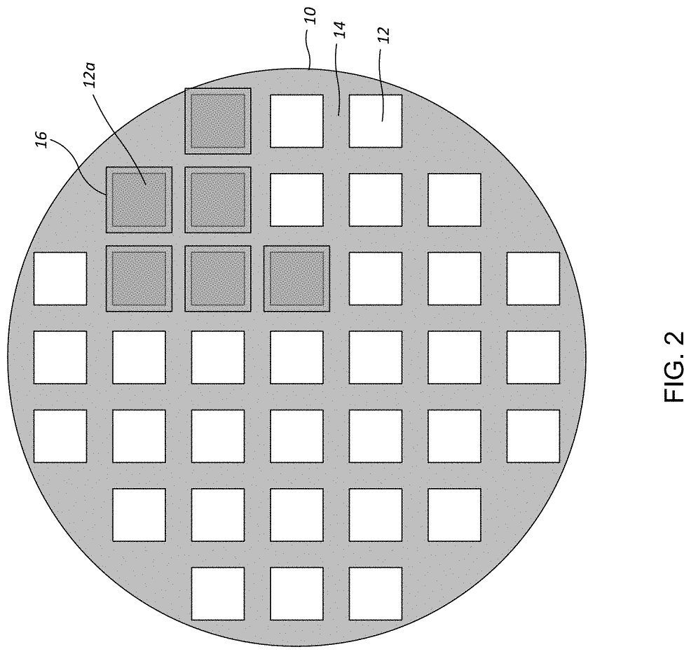

Referring to FIG. 2, a substrate 10 includes multiple dies 12. The dies 12 can separated by scribe lines 14. At least one of the dies 12a needs to have more or less polishing relative to other dies. This might be due to non-uniformity of the incoming substrate, e.g., the layer being thicker or thinner over die 12a compared to other dies, or due to inherent non-uniform polishing rate of polishing by the polishing station 20, or a combination thereof.

The dispenser at the treatment station is used to apply the treatment fluid onto regions 16 of the substrate that correspond to the selected die(s) 12a to adjust the subsequent polishing rate of the selected die(s) 12a at the polishing station. Each region 16 can completely overlap a corresponding selected die 12a. The treatment fluid is not applied to the remaining die(s), i.e., at least one of the dies 12.

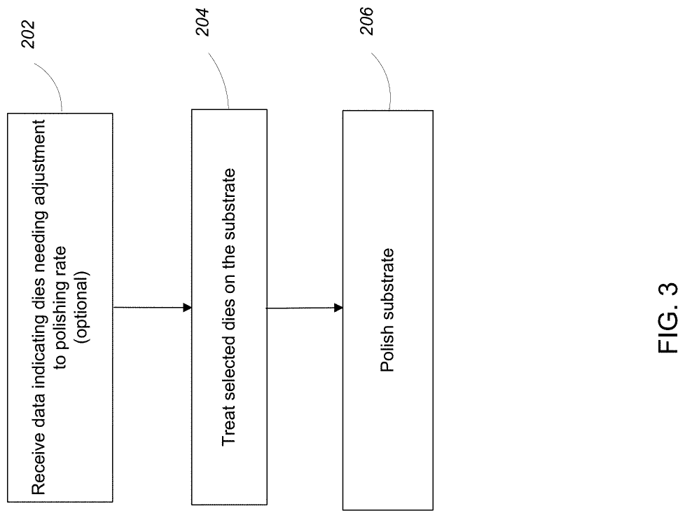

Referring to FIG. 3, a method of operating the polishing apparatus by the control system can optionally include obtaining data indicating which die or dies (aka selected die(s)) on the substrate require treatment (202). The data can also indicate whether the treatment is to increase or decrease the polishing rate.

For example, in a feed-forward technique, the thickness of the layer to be polished can be measured at a position on each of multiple dies on the substrate. The measurement can be performed at an in-line or stand-alone metrology station. Based on the thickness measurements, the controller can determine which dies have a layer thickness that varies by more than a threshold amount from a default thickness value or from an average thickness of the dies. The controller can then store data indicating that these dies are selected for treatment.

As another example, in a feedback technique, the thickness of a layer post-polishing can be measured at a position on each of multiple dies on the substrate. The measurement can be performed at an in-line or stand-alone metrology station. The controller can determine which dies have a layer thickness that varies by more than a threshold amount from a default thickness value or from an average thickness of the dies. The controller can then store data indicating that corresponding dies on a subsequent substrate are selected for treatment.

As yet another example, the data indicating which die or dies on the substrate require treatment can be received by user input, e.g., based on prior empirical measurements.

The substrate is loaded into the treatment station and the selected dies are treated with the treatment fluid (204). The treatment locally increases or reduces the material removal amount in specific dies in the subsequent CMP polishing process.

In some implementations, the control system controls operation of the dispenser to selectively dispense the treatment fluid to the selected die(s) based on the data. For example, a droplet ejection printer can be controlled in conjunction with movement of the printer by the actuator to deliver the treatment fluid only on the selected die(s).

As yet another example, data indicating which die or dies on the substrate require treatment is not stored by the controller, but the selection of which die(s) are treated is controlled by the physical configuration of the treatment station, e.g., the position of the apertures in the mask. The design of the mask can be based on prior empirical measurements.

In some implementations, the treatment includes forming a protective film on the selected dies. The protective film can be a layer of organic materials, e.g., cross-linkable polymers, or can be a layer of inorganic material, e.g., liquid glass. The protective film can be thin compared to the layer to be polished, e.g., not more than 10%, e.g., not more than 5%, e.g., not more than 2.5% of the thickness of the layer to be polished.

The protective film can be removed in the subsequent polishing process, but doing so uses time that is not spent polishing the layer. The time needed by the polishing process to remove the protective film depends on the physical properties of the protective film, e.g., thickness, molecular weight, degree of cross-linking. In some implementations, the thickness of protective film, or the degree of curing (by time of exposure or intensity of the energy source) is controlled by the control system in accord with the data indicating to scale with the difference between the layer thickness of the layer at the selected die and the default thinness or average thickness value.

In some implementations, the treatment includes a “destructive” process that damages the layer to be polished on the selected die(s) to make the polishing process more effective, i.e., higher polishing rate. The destructive process can include formation of micro-cracks or surface damage through sonication nozzles and kinetic energy, or by delivering chemical etchant and surface corrosion. This destructive process can occur without actual reduction of the thickness of the layer on the selected die(s). The thickness of the weakened portion of the layer can depend on the sonication power, chemical flow rate, treatment time, etc.

In some implementations, the treatment includes forming a surface monolayer on the selected die(s). The surface monolayer can alter the surface hydrophilicity and impact the interaction between the polishing fluid and the surface of the layer on the selected die(s). The initial removal rate of the selected dies can higher or lower than the dies without treatment, e.g., depending on the degree of hydrophilicity or hydrophobicity, until the surface monolayer is completely removed.

In some implementations, the treatment includes forming a surface layer of a different material on the layer of the selected die(s). For example, by applying certain oxidizers, the surface of a metal layer, e.g., a Cu or W layer, of the selected die(s) can be oxidized to different state that can either have higher or lower removal rate with a given CMP polishing liquid. The surface of specific dies can also be treated with inhibitors or promoters to alter the initial CMP removal rate in the following step.

Overall, for any of the above techniques, the treatment conditions can depend on the removal amount delta that is needed for each die. The removal amount delta can be determined from CMP upstream process such as the etching depth for each die, from the post-CMP die measurement information acquired on previous wafers polish in the same CMP process, from CMP in-situ metrology information such as the remaining film thickness acquired on each die on current wafer, or a combination of these information. Once the removal amount delta is determined for specific die, the treatment conditions such as treatment time, chemical flow, temperature, UV intensity, cure time, etc. can be determined accordingly.

Following treatment, the substrate is subject to a chemical mechanical polishing process (206) at the polishing station.

Although the techniques above discuss treatment before the CMP polishing step, the treatment can be applied in the middle of a CMP polishing process, e.g., by removing the substrate from the polishing station, before continuing the CMP polishing. In addition, the treatment can be performed before after polishing at polishing station, but before polishing at a subsequent polishing station, buffing station or rework station.

Although FIG. 2 illustrates the treatment applied to individual dies, the treatment can also be applied to specific areas of a substrate so as to cover multiple dies. For example, the treatment can be applied to a specific radius of a pie, cone, or other shapes. The treatment can also be applied within a die on specific features of interest.

The hardware to perform the pre-CMP treatment can be installed on the wafer-polishing unloading/loading area, or on the pathway in between of two CMP polishing chambers. The unique advantage of having such pre-CMP treatment hardware on a dual head per polishing chamber system is that when one wafer is under treatment before advancing to the polishing chamber, there is another wafer polishing in the chamber, so performing pre-CMP treatment to CMP throughput is very minimal.

As used in the instant specification, the term substrate can include, for example, a product substrate (e.g., which includes multiple memory or processor dies), a test substrate, a bare substrate, and a gating substrate. The substrate can be at various stages of integrated circuit fabrication, e.g., the substrate can be a bare wafer, or it can include one or more deposited and/or patterned layers. The term substrate can include circular disks and rectangular sheets.

The above described polishing apparatus and methods can be applied in a variety of polishing systems. Either the polishing pad, or the carrier heads, or both can move to provide relative motion between the polishing surface and the substrate. For example, the platen may orbit rather than rotate. The polishing pad can be a circular (or some other shape) pad secured to the platen. Some aspects of the endpoint detection system may be applicable to linear polishing systems, e.g., where the polishing pad is a continuous or a reel-to-reel belt that moves linearly. The polishing layer can be a standard (for example, polyurethane with or without fillers) polishing material, a soft material, or a fixed-abrasive material. Terms of relative positioning are used; it should be understood that the polishing surface and substrate can be held in a vertical orientation or some other orientation.

Control of the various systems and processes described in this specification, or portions of them, can be implemented in a computer program product that includes instructions that are stored on one or more non-transitory machine-readable storage media, and that are executable on one or more processing devices. The systems described in this specification, or portions of them, can be implemented as an apparatus, method, or electronic system that may include one or more processing devices and memory to store executable instructions to perform the operations described in this specification.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Accordingly, other embodiments are within the scope of the following claims.

What is claimed is:

1. A method of processing a substrate, comprising:
selectively dispensing a treatment fluid on a die-by-die basis to onto a substrate; and
chemical mechanical polishing the substrate after dispensing the treatment fluid, wherein the treatment fluid modifies a polishing rate of the chemical mechanical polishing at one or more selected die(s) to which the treatment fluid is applied in comparison to one or more remaining die(s) to which the treatment fluid is not applied.

2. The method of claim 1, wherein selectively dispensing the treatment fluid comprises one or more of ejection droplet printing, spin-on coating, spray-on, or screen printing.

3. The method of claim 2, wherein selectively dispensing comprises flowing the treatment fluid through a mask.

4. The method of claim 2, wherein selectively dispensing comprises selectively ejecting droplets of the treatment fluid onto the substrate.

5. The method of claim 2, wherein selectively dispensing comprises disposing the treatment fluid across all of the dies on the substrate and curing the treatment fluid at the one or more selected die(s).

6. The method of claim 1, further comprising curing the treatment fluid before chemical mechanical polishing the substrate.

7. The method of claim 1, comprising forming the treatment fluid into a protective film that reduces the polishing rate at the selected die(s) relative to the remaining die(s).

8. The method of claim 1, wherein the treatment fluid damages a layer to be polished so as to increase the polishing rate at the selected die(s) relative to the remaining die(s).

9. The method of claim 1, wherein the treatment fluid forms a monolayer that adjusts a hydrophilicity of the selected die(s) relative to the remaining die(s).

10. The method of claim 1, comprising measuring thicknesses of a layer at a plurality of locations corresponding to a plurality of dies on the substrate, and determining the selected die(s) based on the thicknesses.

11. A system comprising:
a treatment station including a dispenser to deliver a treatment fluid on a die-by-die basis to onto a substrate, wherein the treatment fluid modifies a polishing rate at one or more selected die(s) to which the treatment fluid is applied in comparison to one or more remaining die(s) to which the treatment fluid is not applied in a subsequent chemical mechanical polishing; and
a chemical mechanical polishing station; and
a substrate transfer robot to transfer the substrate from the treatment station to the chemical mechanical polishing station.

12. The system of claim 11, wherein the dispenser comprises one or more of an ejection droplet printer, spin-on coater, spray-on coater, or screen printer.

13. The system of claim 11, wherein the treatment station includes a mask positioned to block the treatment fluid from being applied to the remaining die(s).

14. The system of claim 11, wherein the treatment station includes an energy source to cure the treatment fluid.

15. The system of claim 14, comprising a control system coupled to the energy source and configured to selectively activate the energy source such that the treatment fluid is cured at the selected die(s).

16. The system of claim 11, wherein the dispenser comprises a transducer to apply sound energy to the treatment fluid and cause sonication of a layer on the substrate at the selected die(s).

17. The system of claim 11, further comprising a control system configured to obtain data indicating the selected die(s) and to control the dispenser to apply the treatment fluid at the selected die(s).

18. The system of claim 17, wherein the control system is configured to receive a plurality of thickness measurements for a plurality of locations corresponding to a plurality of dies on the substrate, and to determine the selected die(s) based on the plurality of thickness measurements.

19. The system of claim 18, comprising an in-line or stand-alone metrology system to make the plurality of thickness measurements on the substrate.
